(19) United States
(12) Patent Application Publication
(10) Pub. No.: US 2016/0195656 A1
(43) Pub. Date: Jul. 7, 2016

(54) STRUCTURE OF ULTRAVIOLET LIGHT POLARIZATION COMPONENT AND MANUFACTURING PROCESS THEREFOR

(71) Applicant: NATIONAL APPLIED RESEARCH LABORATORIES, Taipei (TW)

(72) Inventors: Po-Kai CHIU, Taipei (TW); Chih-Hao ZENG, Taipei (TW); Don-Yau CHIANG, Taipei (TW); Chien-Yue CHEN, Taipei (TW); Chien-Nan HSIAO, Taipei (TW); Fong-Zhi CHEN, Taipei (TW)

(21) Appl. No.: 14/591,099

(22) Filed: Jan. 7, 2015

(51) Int. Cl. G02B 5/30; C23C 14/34; C23C 16/50; C23C 16/455; C23C 16/18

(52) U.S. Cl. CPC G02B 5/3075; G02B 5/3041; C23C 16/45525; C23C 16/18; C23C 16/50; C23C 14/34

(57) ABSTRACT

A structure of an ultraviolet light polarization component and a manufacturing process thereof, where a multi-layer thin film structure set is plated on a transparent falt substrate, and the multi-layer structure setis composed of a low refractive index thin film layer stacked for N times and a high refractive index thin film layer. The violet light is polarized into two polarization lights through the ultraviolet light polarization component, in which the two violet lights have a polarization ratio of larger than 10, so that the technical efficacy of realization of a small volume optical component and a large incident angle of the ultraviolet light.

### BACKGROUND OF RELATED ART

1. Technical Field

The present invention relates to an optical structure and a manufacturing process, and particularly to a structure of an ultraviolet polarization component and a manufacturing process thereof.

2. Related Art

Lithography technique is the most widely employed manufacturing technique in the semiconductor industry. With the requirement of lightness and compactness along with the simultaneous strong functions, particularly the satisfaction with the Moore's Law for the semiconductor device density, the lithography process has to be used by using a mask, a resistant and an exposure process.

Recently years, the semiconductor manufacturing process has been applied onto a display, which closely involves the resolution issue. A high numerical aperture optical system may increase the resolution of the display.

The resolution of a device is closely related to a wavelength and a numerical aperture. In a mathematical expression, a reachable minimum recognition rate is propotional to the adopted optical wavelength and inversely proportional to the numerical aperture. Namely, to obtain a device having a high resolution, the adopted numerical aperture may use a possibly high numerical aperture and a possibly low numerical aperture.

However, an optical system having a high nuerical aperture is difficult to be implemented. Therefore, using a polarized ultraviolet light may lend a high resolution display to be possible, thereby further enhancing the lithography technique' s development.

The prior art optical polarization component contains two lenses, in which one is a lens having been particularly processed in plating and an optical solification bonding layer is disposed between the two lenses for bonding. In the following, the prior art will be briefly described.

U.S. Pat. No. 6,480,330, “Ultraviolet polarization beam splitter for micro- lithography” disclosed an ultraviolet light polarization component, some fluoride, such as GdF₃ and AlF₃, thin film layers are stacked to form a structure for the ultraviolet light polarization component.

US patent application, US 20060158591, “Light polarizing film” disclosed a technique for linear spectropoloarizing through a polypropylene thin film at the visible light wavelength range and an indred light wavelength range.

Taiwan Patent, TW 201133030 “Spectropolarizer and optical system” disclosed a technique achieving a spectropolarization effect by using an alignment layer and a choleteral liquid crystal layer.

In the above techniques, the optical polarization components are all achieved by cotating particularly a thin film on a lens, and which is then bonded with the other transparent lens.

However, this type of optical polarization components has the disadvantages that its volume is very large and the optical solidation bonding manner is required to form the optical polarization component, which may adversely affects an optical transmittance and have bubbles generated. To solve these issues, such optical polarization component based on the optical thin film principle with plating on a flat glass is developed. Such prior art will be described as follows.

Europe patent, EU 1892543, “Cartesian polarizers utilizing photo-aligned liquid crystals” , and US patent application, 20040074261, “Optical article comprising a quarter-wave plate and method for making same” disclosed a structure of having a thin film plated on surface of a flat glass, respectively. However, such device may be only suitable for the visible wavelength range and used as an n anti-reflective thin film. At the same time, different device manufacturing manners may result in different functions. However, this type of optical polarization component may not have the optical polarization effects with a high incident angle and suitable for the ultraviolet light as had in the above bonding polarization component that a high incident angle.

In view of the above, it may be known that there ahs been the issues that the bonding optical polarization component has an exceeding large volume and the optical polarization component based on plating may not be suitable for the high incident angle ultraviolet light. Therefore, there is quite a need to set forth an improvement means to settle down this problem.

### SUMMARY

In view of the issues encountered in the prior art that the bonding optical polarization component has an exceedingly large volume, and a high incident angle of the ultraviolet light polarization, the present invention provides a structure of an ultraviolet light polarization component and a manufacturing process of a structure of an ultraviolet light polarization component, which may achieve the technical efficacy of realization of a small volume optical component and a large incident angle of the ultraviolet light.

According to the present invention, the structure of the ultraviolet polarization component comprises a transparent flat substrate; and a multi-layer thin film structure set, being plated on a surface of the transparent flat substrate, and being composed of a low refractive index thin film layer and a high refractive index thin film layer being stacked for N times repeatedly, refractive index of the high refractive thin film layer and refractive index of the low refractive thin film layer having a difference larger than 0.1, and N is a positive integer, wherein two polarized light are polarized from ultraviolet light which has an incident angle ranges from 55 degrees to 85 degrees by the ultraviolet polarization component and polarization ratio of the two polarized light larger than 10.

In the structure of the ultraviolet polarization component, the transparent flat substrate includes a quartz glass substrate, an oxide glass substrate, and a fluoride glass substrate.

In the structure of the ultraviolet polarization component, the high refractive index thin film layer is plated with one of an oxide and a fluoride having a refractive index larger than a refractive index of the transparent flat substrate.

In the structure of the ultraviolet polarization component, the low refractive index thin film layer is plated with one of the oxide and the fluoride having a refractive index smaller than the refractive index of the transparent flat substrate.

In the structure of the ultraviolet polarization component, the high refractive index thin film layer and the low refractive index thin film layer each have a thickness ranges from 0.1 nm to 300 nm.

In the structure of the ultraviolet polarization component, the multi-layer thin film structure set is composed of the low refractive index thin film layer and the high refractive index thin film layer being stacked for N times repeatedly, and N ranges from 1 to 990.

In the structure of the ultraviolet polarization component, the ultraviolet light has a wavelength ranges from 150 nm to 436 nm.

In the structure of the ultraviolet polarization component, the multi-layer thin film structure set is manufactured by a composition selected from a group consisting of the high refractive index thin film layer is first plated and then a pair plated by the low refractive index thin film layer and the high refractive index thin film layer is plated thereon by N times as a stack; the low refractive index thin film layer is first plated and then a pair plated by the low refractive index thin film layer and the high refractive index thin film layer is plated thereon by N times as a stack; the low refractive index thin film layer is first plated and then the high refractive index thin film layer is plated thereon as a pair, and then the pair is plated by N times as a stack, and then the high refractive index thin film layer is plated on the stack; and the low refractive index thin film layer is first plated and then the high refractive index thin film layer is plated thereon as a pair, and then the pair is plated by N times as a stack, and then the low refractive index thin film layer is plated on the stack.

In the structure of the ultraviolet polarization component, the multi-layer thin film structure set is plated on the surface of the transparent flat substrate by a manufacturing process selected from a group consisting of sputtering process, an evaporation process, an atomic layer deposition system process, metal-organic chemical vapor deposition (MOCVD), and a plasma-enhancedx chemical vapor deposition (PECVD).

According to the present invention, the manufacturing process for manufacturing a structure of an ultraviolet polarization component comprises steps of providing a surface of a transparent flat substrate; plating a multi-layer thin film structure set on the transparent flat substrate, the multi-layer thin film structure set being composed of a low refractive index thin film layer and a high refractive index thin film layer being stacked for N times repeatedly, and refractive index of the high refractive thin film layer and refractive index of the low refractive thin film layer having a difference larger than 0.1, and N is a positive integer, wherein two polarized light are polarized from ultraviolet light which has an incident angle ranges from 55 degrees to 85 degrees by the ultraviolet polarization component and polarization ratio of the two polarized light larger than 10.

In the manufacturing process for manufacturing the structure of the ultraviolet polarization component, the transparent flat substrate includes a quartz glass substrate, an oxide glass substrate, and a fluoride glass substrate.

In the manufacturing process for manufacturing the structure of the ultraviolet polarization component, the high refractive index thin film layer is plated with one of an oxide and a fluoride having a refractive index larger than a refractive index of the transparent flat substrate.

In the manufacturing process for manufacturing the structure of the ultraviolet polarization component, the low refractive index thin film layer is plated with one of the oxide and the fluoride having a refractive index smaller than the refractive index of the transparent flat substrate.

In the manufacturing process for manufacturing the structure of the ultraviolet polarization component, the high refractive index thin film layer and the low refractive index thin film layer each have a thickness ranges from 0.1 nm to 300 nm.

In the manufacturing process for manufacturing the structure of the ultraviolet polarization component, the multi-layer thin film structure set is composed of the low refractive index thin film layer and the high refractive index thin film layer being stacked for N times repeatedly, and N ranges from 1 to 990.

In the manufacturing process for manufacturing the structure of the ultraviolet polarization component, the ultraviolet light has a wavelength ranges from 150 nm to 436 nm.

In the manufacturing process for manufacturing the structure of the ultraviolet polarization component, the multi-layer thin film structure set is manufactured by a composition selected from a group consisting of the high refractive index thin film layer is first plated and then a pair plated by the low refractive index thin film layer and the high refractive index thin film layer is plated thereon by N times as a stack; the low refractive index thin film layer is first plated and then a pair plated by the low refractive index thin film layer and the high refractive index thin film layer is plated thereon by N times as a stack; the low refractive index thin film layer is first plated and then the high refractive index thin film layer is plated thereon as a pair, and then the pair is plated by N times as a stack, and then the high refractive index thin film layer is plated on the stack; and the low refractive index thin film layer is first plated and then the high refractive index thin film layer is plated thereon as a pair, and then the pair is plated by N times as a stack, and then the low refractive index thin film layer is plated on the stack.

In the manufacturing process for manufacturing the structure of an ultraviolet polarization component, the multi-layer thin film structure set is plated on the surface of the transparent flat substrate by a manufacturing process selected from a group consisting of sputtering process, an evaporation process, an atomic layer deposition system process, metal-organic chemical vapor deposition (MOCVD), and a plasma-enhanced chemical vapor deposition (PECVD).

The present invention has the difference as compared to the prior art that the multi-layer thin film structure set is plated on the transparent falt substrate, the multi-layer structure setis composed of the low refractive index thin film layer stacked for N times and the high refractive index thin film layer, the violet light is polarized into two polarization lights through the ultraviolet light polarization component, in which the two violet lights have a polarization ratio of larger than 10.

By using the above technical means, the present invention may achieve the technical efficacy of realization of a small volume optical component and a large incident angle of the ultraviolet light.

### BRIEF DESCRIPTION OF THE DRAWINGS

The present invention will be better understood from the following detailed descriptions of the preferred embodiments according to the present invention, taken in conjunction with the accompanying drawings, in which:

FIG. 1A through FIG. 1D are schematic diagrams of a structure of an ultraviolet light polarization component according to the present invention, respectively;

FIG. 2 is a flowchart of a manufacturing process of manufacturing the structure of the ultraviolet light polarization component according to the present invention;

FIG. 3 is a schematic diagram of a polarized ultraviolet light path associated with the ultraviolet polarization component according to the present invention; and

FIG. 4 is an actual data diagram of the polarized ultraviolet light associated with the ultraviolet polarization component according to the present invention.

### DETAILED DESCRIPTION

The present invention will be apparent from the following detailed description, which proceeds with reference to the accompanying drawings, wherein the same references relate to the same components.

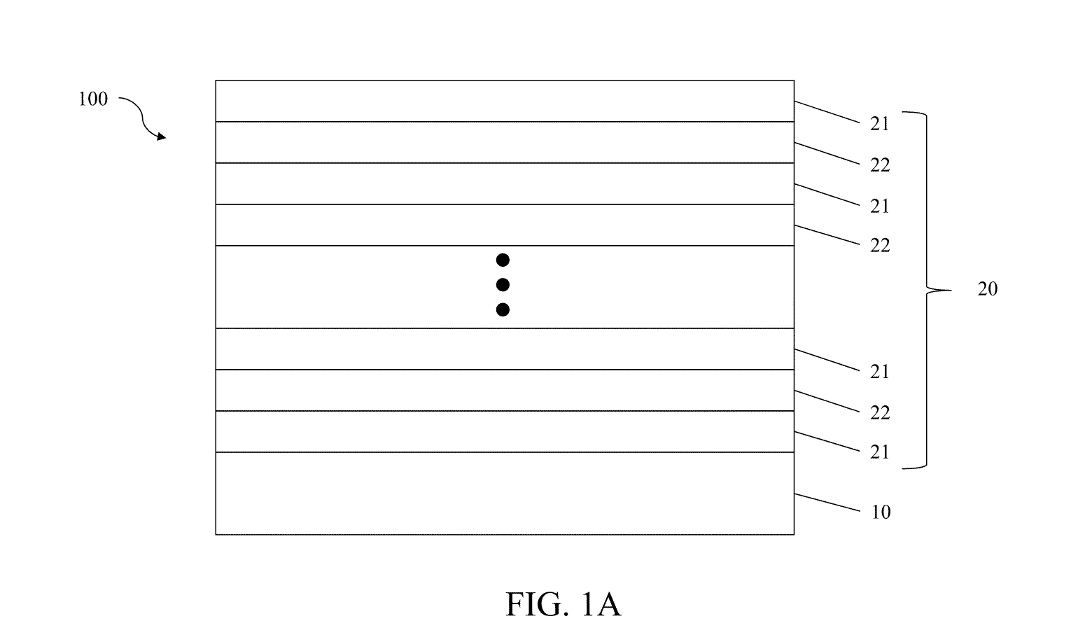

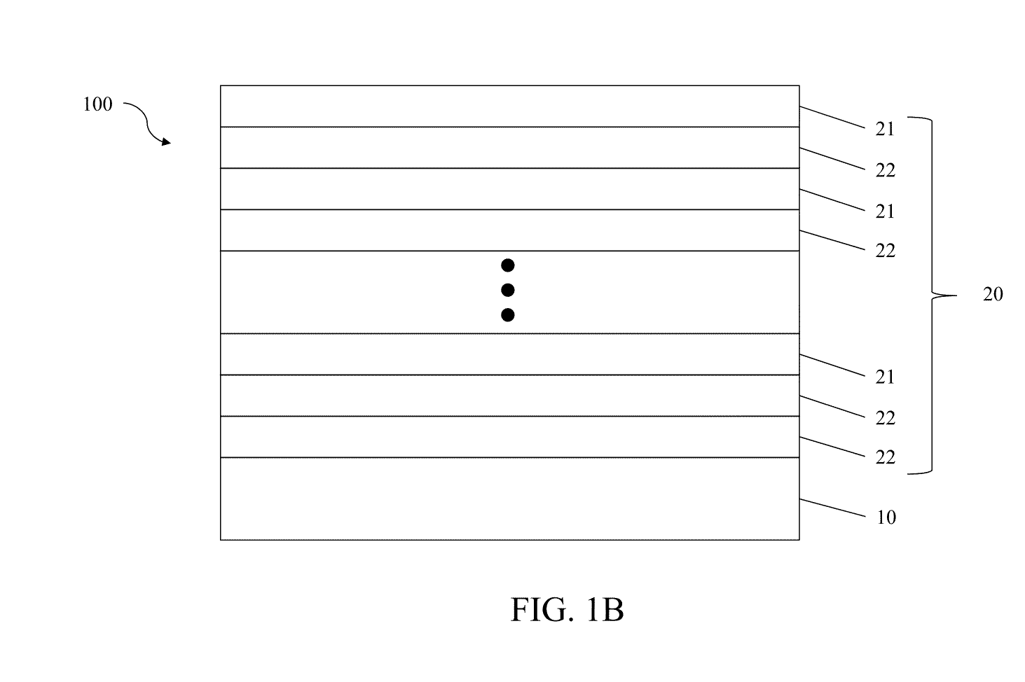

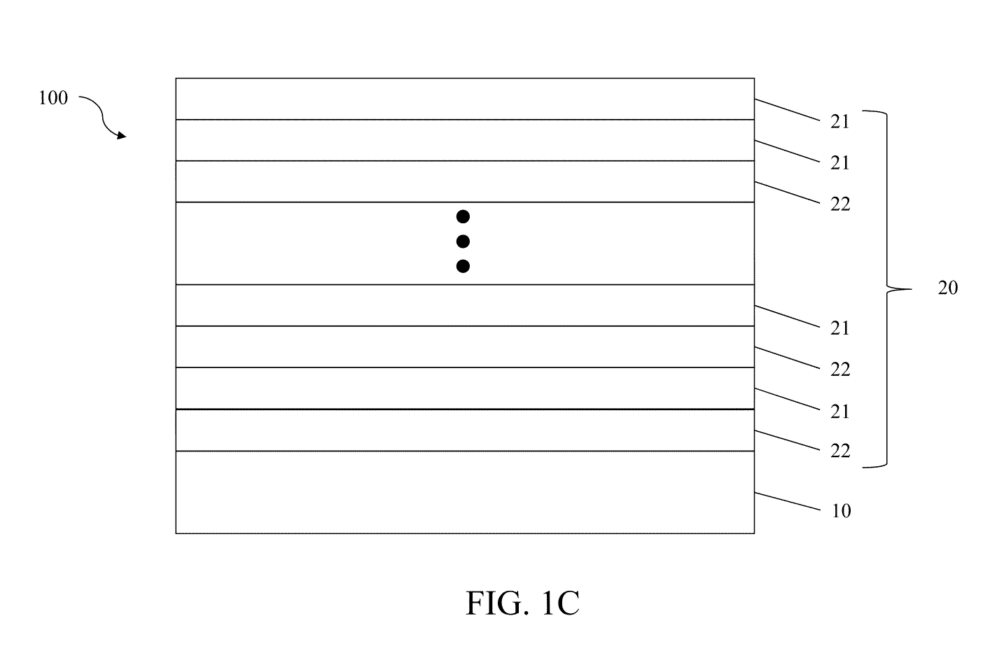

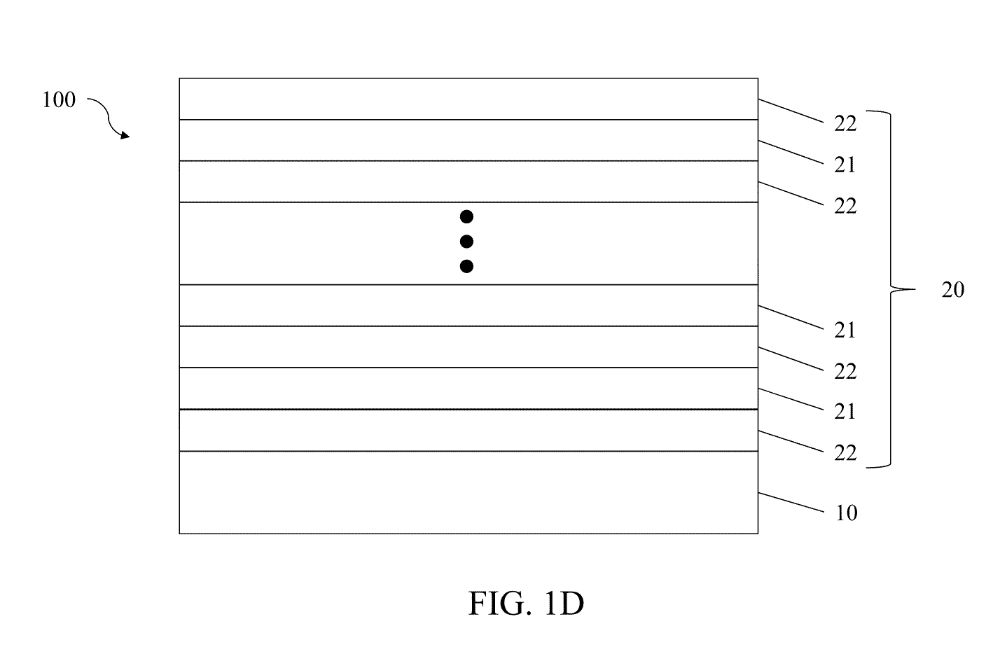

In the following, a structure of an ultraviolet light polarization component according to the present invention will be first described, with simultaneous reference to FIG. 1A through FIG. 1D, which are schematic diagrams of a structure of an ultraviolet light polarization component according to the present invention, respectively.

The ultraviolet light polarization component 100 has its structure comprising a transparent flat substrate 10 and a multi-layer thin film structure set 20.

The transparent flat substrate 10 has a flat shape, and may be transparent for an ultraviolet light. Namely, the transparent flat substrate 10 may be a quartz glass substrate, an oxide glass substrate, a fluoride glass substrate, etc. However, these are merely examples without limiting the present invention. Any meeting with the above characteristics may be used as the material for the transparent flat substrate 10.

The multi-layer thin film structure set 20 is plated on a surface of the transparent flat substrate 10 by using a sputtering process, an evaporation process, an atomic layer deposition system process, a metal-organic chemical vapor depositon (MOCVD), and a plasma-enhanced chemical vapor deposition (PECVD). However, these are merely examples without limiting the present invention.

Assume in an ion source assisted electronic gun evaporation process, several types of gas are provided onto the multi-layer thin film structure set 20 to obtain some optical characteristics at the ultraviolet wavelength range. The optical characteristics includes compactness, stability, recognition rate of P polarization and S polarization, etc. These are merely examples, without limiting the present invention. In addition, the gas may be oxygen, nitride, argon, etc. These are merely examples, without limiting the present invention. In the ion source assisted electronic gun exaporation process, the vacuum extent may be smaller than 10⁻²Pa, the transparent flat substrate 10 may have a temperature of below 400° C., the ion source power may be ranged from 0 to 1,500 W so that a plating beginning condition may be reached. When an oxide is plated, the vacuum extent is set as smaller than 10⁻¹Pa for plating. When a fluoride is plated, the vacuum extent is set as smaller 10⁻³Pa. And, the high and low refractive index thin films have their plating rate as 1 Å/sec-20 Å/sec, respectively. However, these are merely examples, and any parameters which may be used to control the plating process are to be deemed as within the scope of the present invention in addition to the parameters set forth in the above.

On the transparent flat substrate 10, the low refractive index thin film is plated for repeated N times 22 and the high refractive index thin film layer 21 is also plated, forming an interactive stack of the high refractive thin film 21 and the low refractive index thin films 22, so that the multi-layer structure set 20 is thus plated on the transparent flat substrate 10.

The high refractive index thin film layer has a refractive index difference larger than 0.1 with respect to the low refractive index thin film layer, wherein N is an integer and ranges from 1 to 990.

For the multi-layer thin film structure set 20, the high refractive index thin film 21 may be first plated, and then the low refractive index thin film layer 22 may be plated on the high refractive index thin film 21 as a pair, and this pair pattern is repeated by N times, and then the high refractive index thin film layer 21 is plated on the stack, forming an iterative stack of the high and low refractive index thin films 21, 22. In this manner, the multi-layer thin film structure set 20 is caoted on the transparent flat substrate 10, as shown in FIG. 1A.

The above multi-layer thin film structure set 20 may also be plated by the following manner. A low refractive index thin film 22 may be first plated, and then the low refractive index thin film layer 22 is plated and the high refractive index thin film layer 21 is plated on the latter low refractive index thin film layer 22 as a pair, and the pair pattern is repeated by N times, forming an iterative stack of the high and low refractive index thin films 21, 22. In this manner, the multi-layer thin film structure set 20 is caoted on the transparent flat substrate 10, as shown in FIG. 1B.

Alternatively, the above multi-layer thin film structure set 20 may also be plated by the following manner. The low refractive index thin film 22 and then the high refractive thin film layer is plated thereon as a pair, and then the pair is plated by N times repetition as a stack, and then a such high refractive index thin film layer 21 is plated on the stack, forming an iterative stack of the high and low refractive index thin films 21, 22. In this manner, the multi-layer thin film structure set 20 is caoted on the transparent flat substrate 10, as shown in FIG. 1C.

As another alternative, the above multi-layer thin film structure set 20 may also be plated by the following manner. The low refractive index thin film 22 is first plated and then the high refractive index thin film layer 21 is plated thereon as a pair, and the pair is stacked for N times as a stack, and then a such low refractive index thin film layer 21 is plated on the stack, forming an iterative stack of the high and low refractive index thin films 21, 22. In this manner, the multi-layer thin film structure set 20 is caoted on the transparent flat substrate 10, as shown in FIG. 1D.

The above multi-layer structure sets are such composed as merely examples, without limiting the present invention.

It is to be noted that the high refractive index layer is composed of an oxide or a fluoride having a refractive index larger than that of the transparent flat substrate. However, these are merely examples without limiting the present invention. Specifically, assume the transparent flat substrate is a quartz glass, and then the high refractive index thin film may be plated by HfO₂ or LaF₃. However, these are merely examples without limiting the present invention without limiting the present invention.

It is to be noted that the low refractive index layer is composed of an oxide or a fluoride having a refractive index smaller than that of the transparent flat substrate. However, these are merely examples without limiting the present invention. Specifically, assume the transparent flat substrate is a quartz glass, and then the low refractive index thin film may be plated by SiO₂, Ta₂O₅, or MgF₂. However, these are merely examples without limiting the present invention without limiting the present invention.

In addition, the high and low refractive index thin film layers each have a thickness ranges from 0.1 nm to 300 nm.

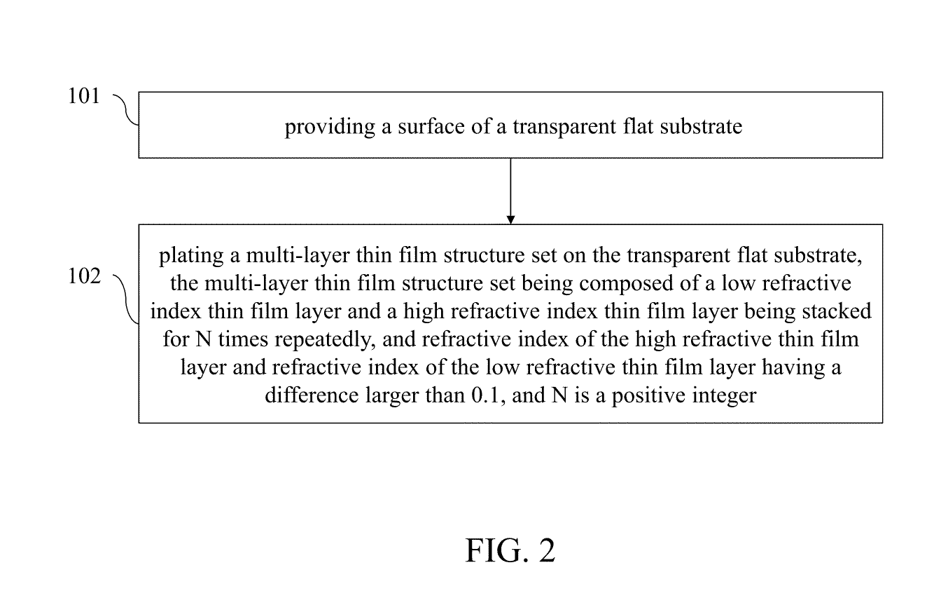

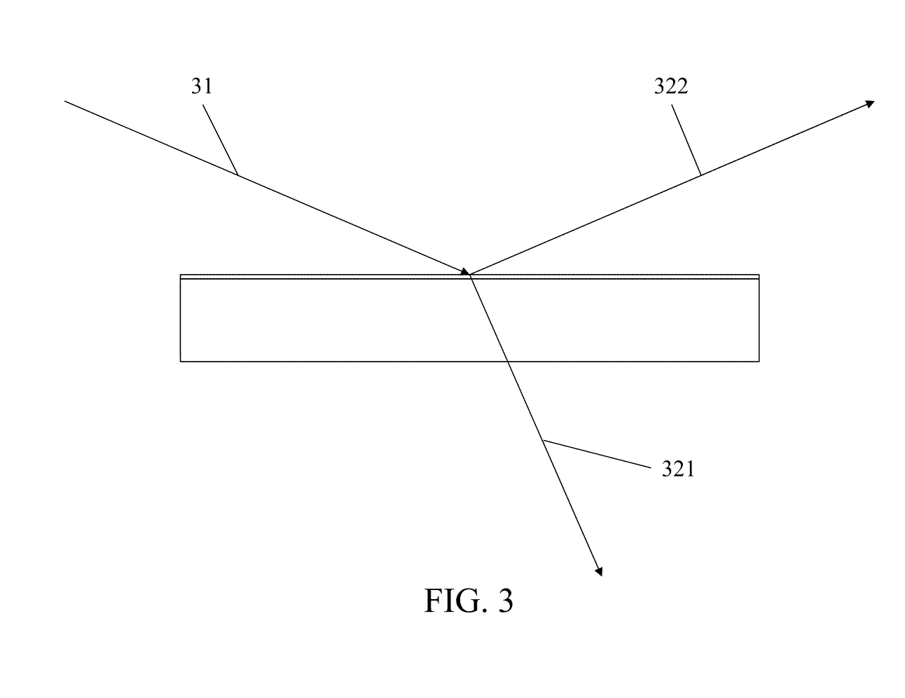

Thereafter, referring to FIG. 2, in which a flowchart of a manufacturing process of manufacturing the structure of the ultraviolet light polarization component according to the present invention is shown.

At first, a transparent flat substrate is provided (S101). The transparent flat substrate 10 has a flat shape, and may be transparent for an ultraviolet light. Namely, the transparent flat substrate 10 may be a quartz glass substrate, an oxide glass substrate, a fluoride glass substrate, etc. However, these are merely examples without limiting the present invention. Any meeting with the above characteristics may be used as the material for the transparent flat substrate 10.

Next, a multi-layer thin film structure set is plated on a surface of the transparent flat substrate, and composed of a low refractive index thin film stacked for repeated N times plus the high refractive index thin film layer 21. The high refractive index thin film layer has a refractive index difference larger than 0.1 with respect to the low refractive index thin film layer, wherein N is an integer (S 102).

The multi-layer thin film structure set is plated on the surface of the transparent flat substrate by using a sputtering process, an evaporation process, an atomic layer deposition system process, a metal-organic chemical vapor depositon (MOCVD), and a plasma-enhanced chemical vapor deposition (PECVD). However, these are merely examples without limiting the present invention.

Assume in an ion source assisted electronic gun evaporation process, several types of gas are provided onto the multi-layer thin film structure set 20 to obtain some optical characteristics at the ultraviolet wavelength range. The optical characteristics includes compactness, stability, recognition rate of P polarization and S polarization, etc. These are merely examples, without limiting the present invention. In addition, the gas may be oxygen, nitride, argon, etc. These are merely examples, without limiting the present invention. In the ion source assisted electronic gun exaporation process, the vacuum extent may be smaller than 10⁻²Pa, the transparent flat substrate 10 may have a temperature of below 400° C., the ion source power may be ranged from 0 to 1,500 W so that a plating beginning condition may be reached. When an oxide is plated, the vacuum extent is set as smaller than 10⁻¹Pa for plating. When a fluoride is plated, the vacuum extent is set as smaller 10⁻³Pa. And, the high and low refractive index thin films have their plating rate as 1 Å/sec-20 Å/sec, respectively. However, these are merely examples, and any parameters which may be used to control the plating process are to be deemed as within the scope of the present invention in addition to the parameters set forth in the above.

On the transparent flat substrate 10, the low and high refractive index thin films 22, 21 are repeated for N times, respectively, and thus forms an iterative stack 20 of the multi-layer thin film structure set 20 composed of the low and high refractive index thin films 22, 21. The high refractive index thin film layer has a refractive index difference larger than 0.1 with respect to the low refractive index thin film layer, wherein N is an integer and ranges from 1 to 990.

For the multi-layer thin film structure set 20, the high refractive index thin film 21 may be first plated, and then the low refractive index thin film layer 22 may be plated on the high refractive index thin film 21 as a pair, and this pair pattern is repeated by N times, and then the high refractive index thin film layer 21 is plated on the stack, forming an iterative stack of the high and low refractive index thin films 21, 22. In this manner, the multi-layer thin film structure set 20 is caoted on the transparent flat substrate 10.

The above multi-layer thin film structure set 20 may also be plated by the following manner. A low refractive index thin film 22 may be first plated, and then the low refractive index thin film layer 22 is plated and the high refractive index thin film layer 21 is plated on the latter low refractive index thin film layer 22 as a pair, and the pair pattern is repeated by N times, forming an iterative stack of the high and low refractive index thin films 21, 22. In this manner, the multi-layer thin film structure set 20 is caoted on the transparent flat substrate 10.

Alternatively, the above multi-layer thin film structure set 20 may also be plated by the following manner. The low refractive index thin film 22 and then the high refractive thin film layer is plated thereon as a pair, and then the pair is plated by N times repetition as a stack, and then a such high refractive index thin film layer 21 is plated on the stack, forming an iterative stack of the high and low refractive index thin films 21, 22. In this manner, the multi-layer thin film structure set 20 is caoted on the transparent flat substrate 10.

As another alternative, the above multi-layer thin film structure set 20 may also be plated by the following manner. The low refractive index thin film 22 is first plated and then the high refractive index thin film layer 21 is plated thereon as a pair, and the pair is stacked for N times as a stack, and then a such low refractive index thin film layer 21 is plated on the stack, forming an iterative stack of the high and low refractive index thin films 21, 22. In this manner, the multi-layer thin film structure set 20 is caoted on the transparent flat substrate 10.

The above multi-layer structure sets are such composed as merely examples, without limiting the present invention.

It is to be noted that the high refractive index layer is composed of an oxide or a fluoride having a refractive index larger than that of the transparent flat substrate. However, these are merely examples without limiting the present invention. Specifically, assume the transparent flat substrate is a quartz glass, and then the high refractive index thin film layer may be plated by HfO₂ or LaF₃. However, these are merely examples without limiting the present invention without limiting the present invention.

It is to be noted that the low refractive index layer is composed of an oxide or a fluoride having a refractive index smaller than that of the transparent flat substrate. However, these are merely examples without limiting the present invention. Specifically, assume the transparent flat substrate is a quartz glass, and then the low refractive index thin film layer may be plated by SiO₂, Ta₂O₅, or MgF₂. However, these are merely examples without limiting the present invention without limiting the present invention.

In addition, the high and low refractive index thin film layers each have a thickness ranges from 0.1 nm to 300 nm.

The ultraviolet polarization component 100 employs a high reflection characteristic of an S polarization light of a quarter wave stack. For the ultraviolet polarization component 100, a TE light (S polarized light) is at a stop band of the component 100, while a TM light (P polarized light) is at a pass band of the component 100, which is a work wavelength range of the spectropolarized light.

When the incidnet light is incident into the ultraviolet polarization component 100 at a high incident angle, such as 55 to 85 degrees, and transmits within the work wavelength range, the TE light will be reflected back, while the TM light will transmit through the transparent flat substrate 10. As such, a spectropolarization is achieved.

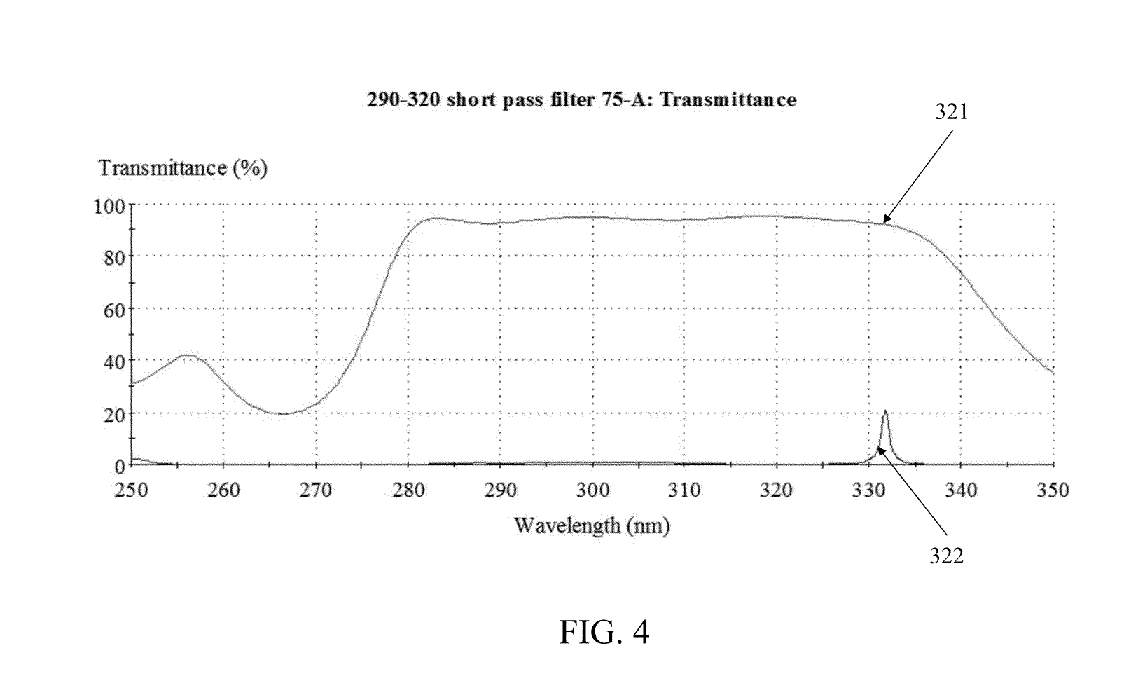

When the incidnet angle is ranged between 55 to 85 degrees, and after the ultraviolet light 31 transmits through the ultraviolet polarization component 100, the ultraviolet light 31 is polarized into two polarization lights, i.e. the P polarization light 321 and the S polarization light 322, with a polarization ratio larger than 10 for the P and S polarization lights 321, 322, wherein the polarization ration is such defined that a transmittance of the P polarization light 321 is divided by a transmittance of the S polarization light 322. In FIG. 4, it may be known that the polarization ratio is larger than 10 when the wavelength range of the ultraviolet light 31 ranges between 150 nm and 436 nm.

In view of the above, it may be known that the present invention has the difference as compared to the prior art that the multi-layer thin film structure set is plated on the transparent falt substrate, the multi-layer structure set is composed of the low refractive index thin film layer stacked for N times and the high refractive index thin film layer, the ultraviolet light is polarized into two polarization lights through the ultraviolet light polarization component, in which the two violet lights have a polarization ratio of larger than 10.

By using the above technical means, the present invention may achieve the technical efficacy of realization of a small volume optical component and a large incident angle of the ultraviolet light.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A structure of an ultraviolet polarization component, comprising:
a transparent flat substrate; and
a multi-layer thin film structure set, being plated on a surface of the transparent flat substrate, and being composed of a low refractive index thin film layer and a high refractive index thin film layer being stacked for N times repeatedly, refractive index of the high refractive thin film layer and refractive index of the low refractive thin film layer having a difference larger than 0.1, and N is a positive integer,
wherein two polarized light are polarized from ultraviolet light which has an incident angle ranges from 55 degrees to 85 degrees by the ultraviolet polarization component and polarization ratio of the two polarized light larger than 10.

2. The structure of an ultraviolet polarization component as claimed in claim 1, wherein the transparent flat substrate includes a quartz glass substrate, an oxide glass substrate, and a fluoride glass substrate.

3. The structure of an ultraviolet polarization component as claimed in claim 1, wherein the high refractive index thin film layer is plated with one of an oxide and a fluoride having a refractive index larger than a refractive index of the transparent flat substrate.

4. The structure of an ultraviolet polarization component as claimed in claim 1, wherein the low refractive index thin film layer is plated with one of the oxide and the fluoride having a refractive index smaller than the refractive index of the transparent flat substrate.

5. The structure of an ultraviolet polarization component as claimed in claim 1, wherein the high refractive index thin film layer and the low refractive index thin film layer each have a thickness ranges from 0.1 nm to 300 nm.

6. The structure of an ultraviolet polarization component as claimed in claim 1, wherein the multi-layer thin film structure set is composed of the low refractive index thin film layer and the high refractive index thin film layer being stacked for N times repeatedly, and N ranges from 1 to 990.

7. The structure of an ultraviolet polarization component as claimed in claim 1, wherein the ultraviolet light has a wavelength ranges from 150 nm to 436 nm.

8. The structure of an ultraviolet polarization component as claimed in claim 1, wherein the multi-layer thin film structure set is manufactured by a composition selected from a group consisting of:
the high refractive index thin film layer is first plated and then a pair plated by the low refractive index thin film layer and the high refractive index thin film layer is plated thereon by N times as a stack;
the low refractive index thin film layer is first plated and then a pair plated by the low refractive index thin film layer and the high refractive index thin film layer is plated thereon by N times as a stack;
the low refractive index thin film layer is first plated and then the high refractive index thin film layer is plated thereon as a pair, and then the pair is plated by N times as a stack, and then the high refractive index thin film layer is plated on the stack; and
the low refractive index thin film layer is first plated and then the high refractive index thin film layer is plated thereon as a pair, and then the pair is plated by N times as a stack, and then the low refractive index thin film layer is plated on the stack.

9. The structure of an ultraviolet polarization component as claimed in claim 1, wherein the multi-layer thin film structure set is plated on the surface of the transparent flat substrate by a manufacturing process selected from a group consisting of sputtering process, an evaporation process, an atomic layer deposition system process, metal-organic chemical vapor deposition (MOCVD), and a plasma-enhancedx chemical vapor deposition (PECVD).

10. A process for manufacturing a structure of an ultraviolet polarization component, comprising steps of:
providing a surface of a transparent flat substrate;
plating a multi-layer thin film structure set on the transparent flat substrate, the multi-layer thin film structure set being composed of a low refractive index thin film layer and a high refractive index thin film layer being stacked for N times repeatedly, and refractive index of the high refractive thin film layer and refractive index of the low refractive thin film layer having a difference larger than 0.1, and N is a positive integer,
wherein two polarized light are polarized from ultraviolet light which has an incident angle ranges from 55 degrees to 85 degrees by the ultraviolet polarization component and polarization ratio of the two polarized light larger than 10.

11. The manufacturing process for manufacturing the structure of the ultraviolet polarization component as claimed in claim 10, wherein the transparent flat substrate includes a quartz glass substrate, an oxide glass substrate, and a fluoride glass substrate.

12. The manufacturing process for manufacturing the structure of the ultraviolet polarization component as claimed in claim 10, wherein the high refractive index thin film layer is plated with one of an oxide and a fluoride having a refractive index larger than a refractive index of the transparent flat substrate.

13. The manufacturing process for manufacturing the structure of the ultraviolet polarization component as claimed in claim 10, wherein the low refractive index thin film layer is plated with one of the oxide and the fluoride having a refractive index smaller than the refractive index of the transparent flat substrate.

14. The manufacturing process for manufacturing the structure of the ultraviolet polarization component as claimed in claim 10, wherein the high refractive index thin film layer and the low refractive index thin film layer each have a thickness ranges from 0.1 nm to 300 nm.

15. The manufacturing process for manufacturing the structure of the ultraviolet polarization component as claimed in claim 10, wherein the multi-layer thin film structure set is composed of the low refractive index thin film layer and the high refractive index thin film layer being stacked for N times repeatedly, and N ranges from 1 to 990.

16. The manufacturing process for manufacturing the structure of the ultraviolet polarization component as claimed in claim 10, wherein the ultraviolet light has a wavelength ranges from 150 nm to 436 nm.

17. The manufacturing process for manufacturing the structure of the ultraviolet polarization component as claimed in claim 10, wherein the multi-layer thin film structure set is manufactured by a composition selected from a group consisting of:
the high refractive index thin film layer is first plated and then a pair plated by the low refractive index thin film layer and the high refractive index thin film layer is plated thereon by N times as a stack;
the low refractive index thin film layer is first plated and then a pair plated by the low refractive index thin film layer and the high refractive index thin film layer is plated thereon by N times as a stack;
the low refractive index thin film layer is first plated and then the high refractive index thin film layer is plated thereon as a pair, and then the pair is plated by N times as a stack, and then the high refractive index thin film layer is plated on the stack; and
the low refractive index thin film layer is first plated and then the high refractive index thin film layer is plated thereon as a pair, and then the pair is plated by N times as a stack, and then the low refractive index thin film layer is plated on the stack.

18. The manufacturing process for manufacturing the structure of an ultraviolet polarization component as claimed in claim 10, wherein the multi-layer thin film structure set is plated on the surface of the transparent flat substrate by a manufacturing process selected from a group consisting of sputtering process, an evaporation process, an atomic layer deposition system process, metal-organic chemical vapor deposition (MOCVD), and a plasma-enhanced chemical vapor deposition (PECVD).
